(19) United States
(12) Patent Application Publication
(10) Pub. No.: US 2002/0000853 A1
(43) Pub. Date: Jan. 3, 2002

(54) DELAY LOCKED LOOP FOR TIMING RECOVERY AND WRITE PRECOMPENSATION FOR A READ CHANNEL OF A MASS DATA STORAGE DEVICE, OR THE LIKE

(76) Inventors: SHIN CHUNG CHEN, LOS GATES, CA (US); FULVIO SPAGNA, SAN JOSE, CA (US)

Correspondence Address: TEXAS INSTRUMENTS INCORPORATED, P O BOX 655474, M/S 3999, DALLAS, TX, 75265

(21) Appl. No.: 09/430,531

(22) Filed: Oct. 29, 1999

(51) Int. Cl. H03L 7/06

(52) U.S. Cl. 327/156

(57) ABSTRACT

An integrated delay locked loop circuit (10) and method are presented. The circuit (10′) includes a source of multiple clock signals (24), each of different relative phase. A plurality of clock selection multiplexers (30-33) are connected to receive the multiple clock signals (16). A control circuit (66) is connected to control each of the plurality of clock selection multiplexers (30-33) to pass a respective selected one of the multiple clock signals (16) to a clock selection output (43-46). If one of the clock selection multiplexers (30-33) is selected to pass a particular one of the clock signals (16) to its clock selection output (43-46), the other clock selection multiplexers are prevented from passing the particular one of the clock signals to their respective clock selection outputs. A plurality of output multiplexers (60-63) are connected to receive outputs from he clock selection multiplexers (30-33). Each of the output multiplexers (60-63) is controlled by the control circuit (66) to select which of the clock selection multiplexer outputs (43-46) is passed to its output.

### BACKGROUND OF THE INVENTION

1. Field of the Invention

This invention relates to improvements an circuits and methods for use in a read channel of a mass data storage device, or hard disk drive, and, more particularly, to improvements in methods and circuits for performing timing recovery and write precompensation in a read channel of a hard disk drive, or the like.

2. Relevant Background

Recently, increased interest has been directed towards increasing the data density of magnetic recordings of digital data on mass data storage devices, such as hard disk drives, or the like. However, as the data becomes more and more densely recorded on the data recording media, the recovery of timing from the read data becomes increasingly difficult. Since the data is written generally in concentric tracks on a rotating magnetic medium, the data recovery timing at outer tracks is significantly differently from the data timing that is recovered from the inner tracks, assuming that the rotating data media is rotated at a constant velocity. Although the technique of varying the rotational speed of the disk has been employed, it has been used primarily in conjunction with floppy disk drives, and is not practical for modern hard disk drives. Thus, special timing circuits have been employed to recover the timing for hard disk drive applications.

Aside from the timing recovery problems, when data is written to a rotating data containing medium, typically a write precompensation technique is employed to provide the necessary delay in writing signals to the disk. A typical circuit 10 that has been employed in the past to accomplish timing recovery and write precompensation is shown in FIG. 1, to which reference is now made.

The circuit 10 employs a conventional phase locked loop (PLL) 12, which includes a four-stage ring oscillator 14, a phase detector 16, a charge pump 18, and a compensator 20. The phase detector 16 compares the phase of the ring oscillator 14 to that of a crystal reference frequency, so that the frequency of the ring oscillator 14 tracks the selected signal.

The output from the PLL 12 provides eight stable clock signals on line 22, each clock signal being of the same frequency and equally spaced from each other by ¼π radians. These clocks are interpolated by a phase interpolator circuit 24 into 64 clocks on line 26. Each of the clocks on line 26 is separated from each other by 1/32π radians.

The clock outputs on line 26 are connected as inputs to a read multiplexer 28 and four write precompensation multiplexers 30-33. The read multiplexer and write precompensation multiplexers typically are transmission gate multiplexers, each having 64 transfer gates and an output driver. The outputs of transfer gates are connected, and thereby form a 64-to-one multiplexer.

The transmission gates of the read multiplexer 28 are controlled by a read mode control signal on line 36 and by read clock select output signals (63:0) on line 38. The read clock select output signals (63:0) are gated within the read multiplexer 28 with read mode signal, and, In the read mode, only one transfer gate is turned “on” as a time to produce a read clock output on line 40. In the write (or in a “non-read”) mode, all the transfer gates are turned “off”, except for the fundamental clock phase φ.

In write pre-compensation (WPC) operation, the first write precompensation multiplexer 30 provides the nominal WPC clock on output line 43 to establish clock phase 0, which is hard selected. The write precompensation multiplexers 31-33 provide level 1 through level 3 WPC clocks on output lines 44-46. The clocks are selected through programming write precompensation decode blocks 50-52. In this design, three programmable 5-bit words, WPC_CLKSEL_LVL1 (4:0), WPC_CLKSEL_LVL2 (4:0), WPC_CLKSEL_LVL3 (4:0)), each of which cover a total of π radians are available to select the desired WPC delay.

One of the problems with the circuit of FIG. 1 is that in the write precompensation multiplexers 31-33, since the outputs of 64 transfer gates are combined into a single output line, the outputs are heavily loaded with metal wiring capacitance. In addition, when duplicate programmed WPC level selection of an identical phase clock occurs in more than one multiplexer, strong interpolator output driving capabilities are required, because multiple multiplexers need to be driven by the same driver. Furthermore, with this situation, uneven loading conditions are imposed among the drivers, which results in drastic loss of precision in the multiplexed clocks.

What is needed therefore is a method that integrates a delay locked loop circuit for write precompensation and timing recovery that offers write precompensation multiplexer capacitance effects and more even loading effects on the clock phase drivers from write precompensation multiplexers than in previous circuits where multiple multiplexers were driven by the same driver.

### SUMMARY OF THE INVENTION

One of the salient advantages realized by the invention is that critical timing signals can be multiplexed while preserving the tight timing relationships among them. Another advantage realized by the invention is a reduction in power requirements from the circuits used heretofore. Still another advantage of the invention is that write precompensation and timing recovery may be achieved in mass data storage devices, or the like, with multiplexers which have reduced write precompensation capacitance effects. Yet another advantage of the invention is that the multiplexers have more even loading effects than previous circuits where multiple multiplexers were driven by the same driver.

These and other objects, features and advantages of the invention will be apparent to those skilled in the art from the following detailed description of the invention, when read in conjunction with the accompanying drawings and appended claims.

Thus, according to a broad aspect of the invention, a delay locked loop (DLL) circuit is presented. The DLL includes a source of multiple clock signals, each of different relative phase. For example, 64 different signals each separated by 1/32π radians may be provided. A plurality of clock selection multiplexers are connected to receive the multiple clock signals, and a control circuit is connected to control the clock selection multiplexers to pass a respective selected one of the multiple clock signals to a clock selection output. If one clock selection multiplexer is selected to pass a particular one of the clock signals, then the other clock selection multiplexers are prevented from passing that particular clock signal. A plurality of output multiplexers are connected to receive outputs from the clock selection multiplexers. Each of the output multiplexers are controlled by the control circuit to select which of the clock selection multiplexer outputs is passed to a circuit output.

According to another broad aspect of the invention, a method is presented for selecting write precompensating clock signals in a mass data storage device. The method includes providing a plurality of clock selection multiplexers to each receive multiple phase separated clock signals. The method also includes providing selection signals to the clock selection multiplexers to pass a respective selected one of the multiple clock signals to a clock selection output. If one clock selection multiplexer is selected to pass a particular one of the clock signals to its clock selection output, the other clock selection multiplexers are prevented from passing the particular one of the clock signals to their respective clock selection outputs. The method also includes providing a plurality of output multiplexers connected to receive outputs from the clock selection multiplexers, and controlling each of the output multiplexers to select which of the clock selection multiplexer outputs is passed as a circuit output.

### BRIEF DESCRIPTION OF THE DRAWINGS

The invention is illustrated in the accompanying drawings, in which:

FIG. 1 is a block diagram of a typical delay locked loop, for use in a read channel of a hard disk drive, or the like, in accordance of the prior art.

FIG. 2 is a block diagram of an integrated delay locked loop, according to a preferred embodiment of the present invention.

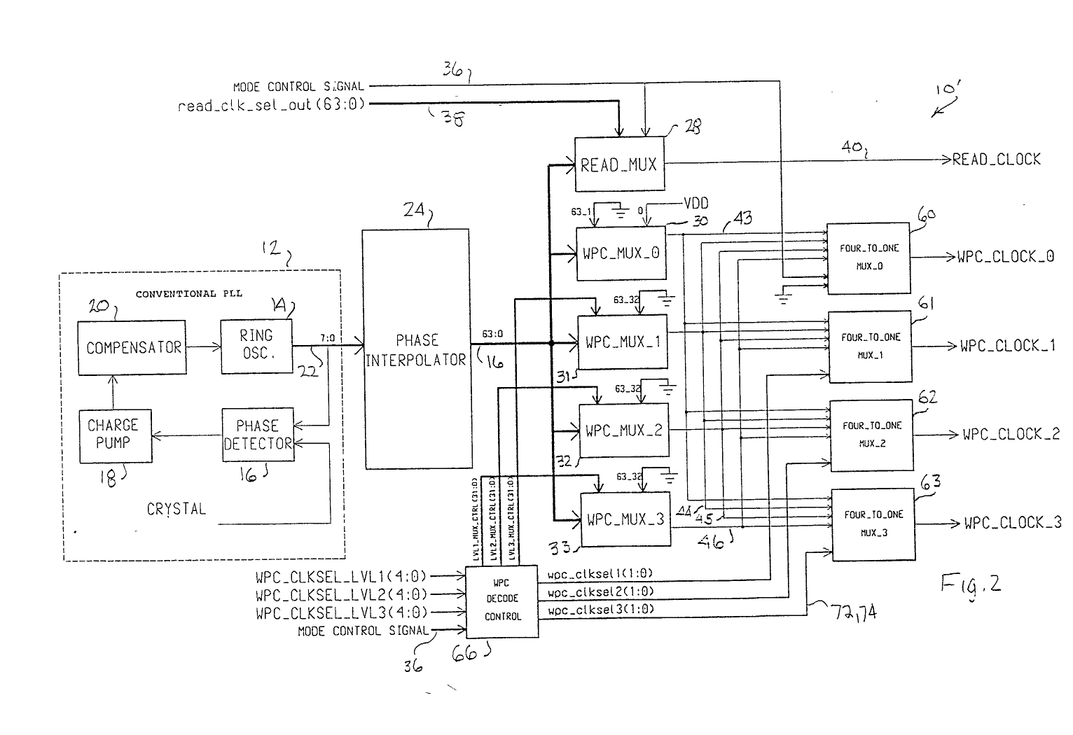

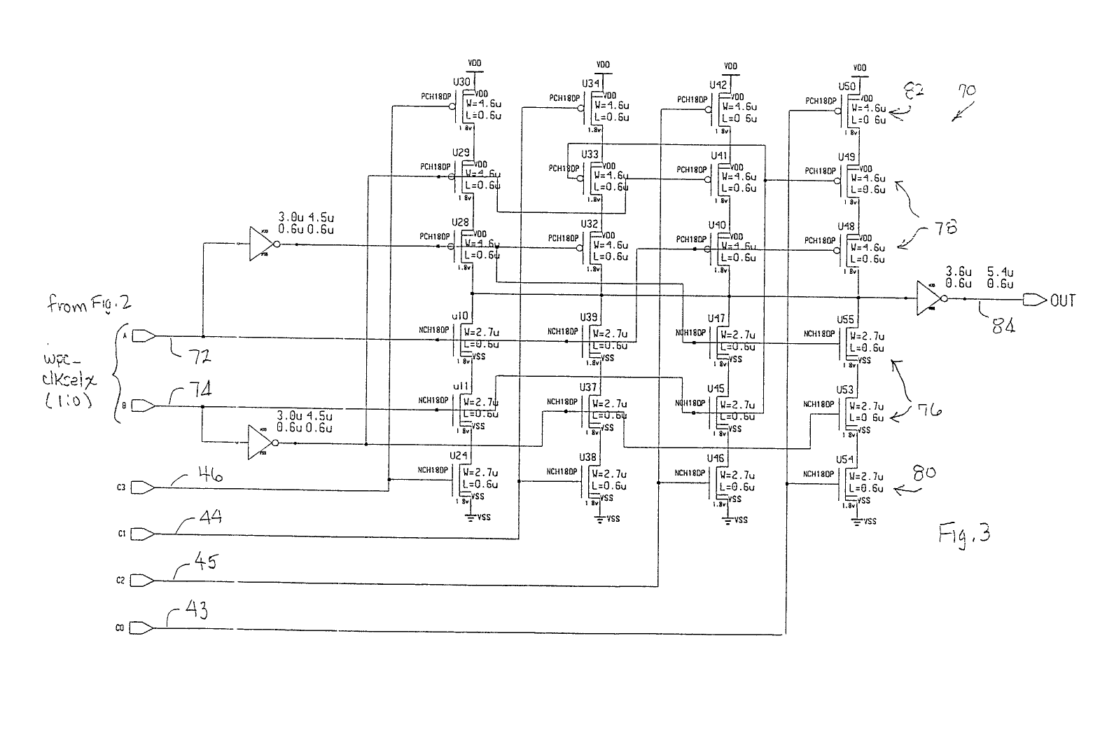

And FIG. 3 is an electrical schematic diagram of a four-to-one multiplexer circuit suitable for use in the delay locked loop of FIG. 2.

In the various figures of the drawing, like reference numerals are used to denote like or similar parts.

### DETAILED DESCRIPTION OF THE PREFERRED EMBODIMENTS

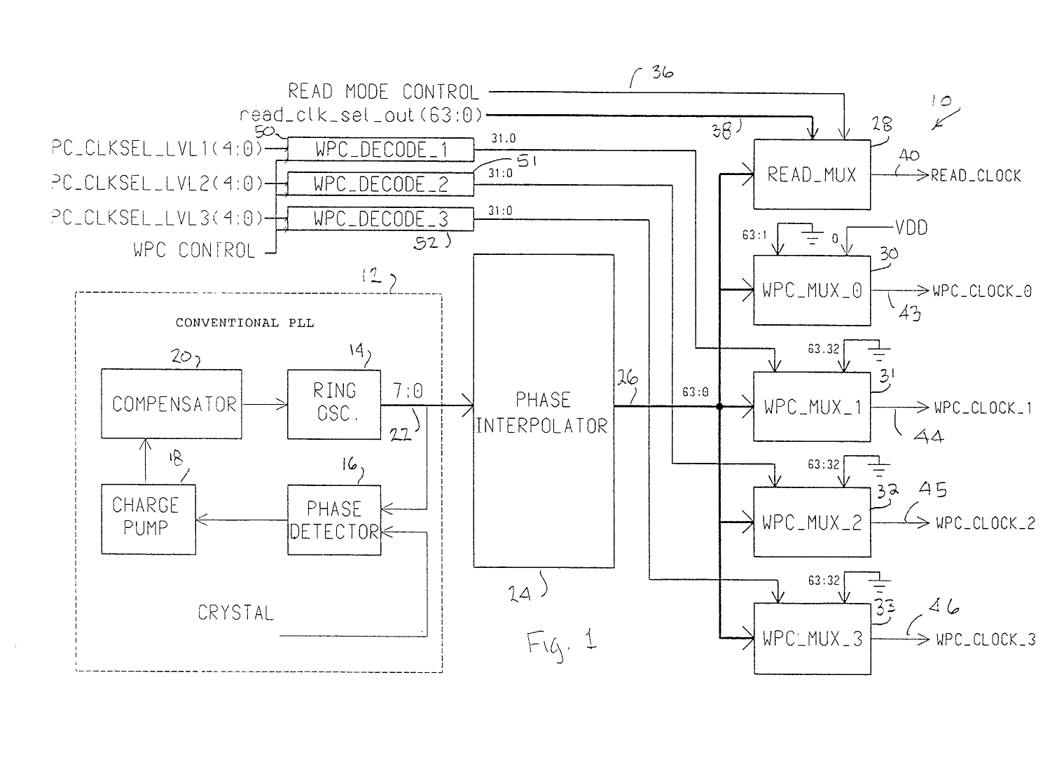

FIG. 2 shows the block diagram of integrated DLL 10′, according to a preferred embodiment of the present invention, to which reference is now made. The circuit of FIG. 2 is similar to the circuit of FIG. 1, except for the addition of a number of 4-to-1 multiplexers 60-61 each being connected to receive the outputs from the write precompensation multiplexers 31-33, and for he addition of a modified write precompensation control circuit 66. An example of an HDL code to realize a hardware embodiment of the write precompensation decode controller 66 is attached as Appendix A.

In this architecture, the loading of each interpolator output driver is substantially the same. Although the circuit of each write precompensation mux's 0-3 is similar to prior art write precompensation multiplexer circuits, no multiple multiplexer driving capabilities are required because of the modified write operation performed by the precompensation control circuit 66. In the write precompensation mode, however, when duplicate programmed write precompensation level selections of an identical phase clock are made, only one of the write precompensation multiplexers 31-33 is allowed to activate, therefore avoiding unequal loading of the phase interpolator output driver. The duplicate clocks associated with the duplicate write precompensation levels, are derived from the output of a single write precompensation multiplexer by means of the write precompensation decode control block 66 and the 4-to-1 multiplexers 60-63. Finally, the 4-to-1 multiplexers 60-63 are constructed such that they evenly load all of the output drivers of the write precompensation multiplexers 31-33.

A preferred embodiment of a 4-to-1 multiplexer circuit 70 that may be used in the circuit 10 is shown in FIG. 3. The circuit 70 is constructed with CMOS transistors to respectively pull up or pull down the output depending upon the state of the signals on the input selection lines 72 which are connected to respective NMOS and PMOS data transistors 80 and 82. As can be seen, the selection lines 72 and 74 are connected to respective NMOS and PMOS selection transistors 76 and 78. The input selection lines 72 and 74 represent, for example, one of the output lines from the write precompensation decode control circuits 66 labeled wpc_clksetx (1:0). It should be noted that each of the 4-to-1 multiplexers 60-63 may be constructed in accordance with the circuits shown in FIG. 3.

Thus it can be seen that depending upon the signal state on the selection lines 72 and 74, the signal that appears on the output lines 42-46 will result in the output pulled down. This effectively isolates the write precompensation multiplexers 30-33 from the outputs provided from the circuit 10′ on the respective output lines, denoted “wpc clock 0-3” shown in FIG. 10′. Moreover, this provides even loads on the different clock phase drivers, which otherwise would create nonlinearities in the phase of the output clock.

Thus, in operation in WPC mode, the write precompensation decode control block 66 compares the three WPC level selections with clock phase 0, the nominal WPC clock. If any of the write precompensation multiplexers 31-33 are programmed to select clock phase 0, it is turned “off”, and the output of the nominal clock multiplexer 30 is gated by the array of 4-to-1 multiplexers 60-63 to the appropriate WPC_CLOCK outputs that share clock phase 0. Similarly, when there are duplicate selections of clock phases other that clock phase 0, only the lowest level one of the write precompensation multiplexers 31-33 is turned “on”, and its output is shared among them.

More particularly, the top write precompensation multiplexer 30 is hard wired to select clock phase 0. If all of the other three write precompensation multiplexers 31-33 also select clock phase 0, then in prior art configurations, all four transfer gates that select clock phase 0 in four write precompensation multiplexers will be turned “ON” and clock phase 0 will be outputted from each one of the four write precompensation multiplexers 30-33.

Thus, in the prior art, the load on the driver of clock phase 0 is four times as high when compared to the invention, if all four write precompensation multiplexers 30-33 were to select four different clock phases. By the same token, if two write precompensation multiplexers select the same particular clock phase, in the prior art, the load on the driver of that particular clock phase will be double loaded. Multiple loads on a clock phase driver will alter he alignment of that clock with respect to the other clocks. However, in the present invention, when there is a multiple selection of a particular clock phases, the WPC_DECODE_CONTROL has the intelligence to know when it happens and will shut “off” all but one of the transfer gates of the write precompensation multiplexers that are associated with gating of that particular clock phase. The output of the write precompensation multiplexer that gates out that particular clock phase is further multiplexed by the one of the 4-to-1 multiplexers 60-63 that is associated with the write precompensation multiplexer that selects that particular clock phase. In this way, exactly one load is put on any clock phase driver, and the precision of the relative phasing of the output clocks is preserved.

Thus, in WPC mode, as mentioned above, due to the intelligence of this architecture, each interpolator output driver (a total of 64 drivers in this example) needs to drive only one of the write precompensation multiplexers 30-33 at a time. This results in a large power saving advantage. In addition, since, with this architecture, the loading conditions of all the WPC level selected clocks are nearly identical, an improvement in the timing precision of the selected clocks may also be realized.

Although the invention has been described and illustrated with a certain degree or particularity, it is understood that the present disclosure has been made only by way of example, and that numerous changes in the combination and arrangement of parts can be resorted to by those skilled in the art without departing from the spirit and scope of the invention, as hereinafter claimed.

Attachment A.

library ieee;
use ieee.std_logic_1164.all;
use ieee.STD_LOGIC_UNSIGNED.all;
use ieee.STD_LOGIC_ARITH.all;
entity tr_wpc_ctrl_decode is

| | | |
|---|---|---|
| port | (mc_sleep_wpc | : in std_logic ; |
| | mc_wg_int | : in std_logic ; |
| | wdp_1pbk_mode | : in std_logic ; |
| | wpc_level1 | : in std_logic_vector (4 downto 0) ; |
| | wpc_level2 | : in std_logic_vector (4 downto 0) ; |
| | wpc_level3 | : in std_logic_vector (4 downto 0) ; |

| | |
|---|---|
| clksl0 | : out std_logic_vector ( 1 downto 0); |
| clksl1 | : out std_logic_vector (31 downto 0); |
| clksl2 | : out std_logic_vector (31 downto 0); |
| clksl3 | : out std_logic_vector (31 downto 0); |
| lvl1_mux_ctrl | : out std_logic_vector (1 downto 0); |
| lvl2_mux_ctrl | : out std_logic_vector (1 downto 0); |
| lvl3_mux_ctrl | : out std_logic_vector (1 downto 0); |
| wpc_decode1_off | : out std_logic; |
| wpc_{—‘decode2_off} | : out std_logic; |
| wpc_{—‘decode3_off} | : out std_logic; |
| wpc_decode1_off_n | : out std_logic; |
| wpc_decode2_off_n | : out std_logic; |
| wpc_decode3_off_n | : out std_logic; |
| ) ; | |
| end; | |

architecture L3 of tr_wpc_ctrl_decode is

| | |
|---|---|
| signal sel3 | : std_logic_vector (4 downto 0); |
| signal sel2 | : std_logic_vector (3 downto 0); |
| signal sel1 | : std_logic_vector (2 downto 0); |

| | |
|---|---|
| signal replace_1by0 | :std_logic; |
| signal replace_2by0 | :std_logic; |
| signal replace_2by1 | :std_logic; |
| signal replace_3by0 | :std_logic; |
| signal replace_3by1 | :std_logic; |
| signal replace_3by2 | :std_logic; |

begin
flags:
process (wpc_level1, wpc_level2,wpc_level3, mc_wg_int,
mc_sleep_wpc)

begin

if (wpc_level1 = “00000”) or (mc_wg_int = ‘0’) or

(mc_sleep_spc = ‘1’) then

| | |
|---|---|
| replace_1by0 | <= ‘1’; |
| wpc_decode1_off | <= ‘1’; |
| wpc_decode1_off_n | <= ‘0’; |

else

| | |
|---|---|
| replace_1by0 | <= ‘0’; |
| wpc_decode1_off | <= ‘0’; |
| wpc_decode1_off_n | <= ‘1’; |

end if;
if (wpc_level2 = “00000”) or (mc_wg_int = ‘0’) or

(mc_sleep_wpc = ‘1’) then

| | |
|---|---|
| replace_2by1 | <= ‘0’; |
| replace_2by0 | <= ‘1’; |
| wpc_decode2_off | <= ‘1’; |
| wpc_decode2_off_n | <= ‘0’; |

elseif wpc_level2 = wpc_level1 then

| | |
|---|---|
| replace_2by1 | <= ‘1’; |
| replace_2by0 | <= ‘0’; |
| wpc_decode2_off | <= ‘1’; |
| wpc_decode2_off_n | <= ‘0’; |

else

| | |
|---|---|
| replace_2by1 | <= ‘0’; |
| replace_2by0 | <= ‘0’; |
| wpc_decode2_off | <= ‘0’; |
| wpc_decode2_off_n | <= ‘1’; |

end if;
if (wpc_level3 = “00000”) or (mc_wg_int = ‘0’) or

(mc_sleep_wpc = ‘1’) then

| | |
|---|---|
| replace_3by2 | <= ‘0’; |
| replace_3by2 | <= ‘0’; |
| replace_3by1 | <= ‘0’; |
| replace_3by0 | <= ‘1’; |
| wpc_decode3_off | <= ‘1’; |
| wpc_decode3_off_n | <= ‘0’; |

elseif wpc_level3 = wpc_level1 then

| | |
|---|---|
| replace_3by2 | <= ‘0’; |
| replace_3by1 | <= ‘1’; |
| replace_3by0 | <= ‘0’; |
| wpc_decode3_off | <= ‘1’; |
| wpc_decode3_off_n | <= ‘0’; |

elseif wpc_level3 = wpc_level2 then

| | |
|---|---|
| replace_3by2 | <= ‘1’; |
| replace_3by1 | <= ‘0’; |
| replace_3by0 | <= ‘0’; |
| wpc_decode3_off | <= ‘1’; |
| wpc_decode3_off_n | <= ‘0’; |

else

| | |
|---|---|
| replace_3by2 | <= ‘0’; |
| replace_3by1 | <= ‘0’; |
| replace_3by0 | <= ‘0’; |
| wpc_decode3_off | <= ‘0’; |
| wpc_decode3_off_n | <= ‘1’; |

end if;

end process flags;
level0_clock:
process (wdp_lpbk_mode)

begin

case wdp_lpbk_mode is

when ‘1’ =>

clksel0 <= “10”;

end if;

when others =>

clksel0 <= “01”;

end case;

end process level0_clock;
level1_clock:
process (mc_sleep_wpc, mc_wg_int, replace_1by0, wpc_level1)

variable m : integer;

begin
if (mc_sleep_wpc or (not mc_wg_int) or

replace_1by0 ) = ‘1’ then

clksel1 <= (others => ‘0’);

else

m := CONV_INTEGER ( wpc_level1 );
for i in clksel1‘range loop
if i = m then

clksel1(i) <= ‘1’;

else

clksel1(i) <= ‘0’;

end if;

end loop;

end if;

end process level1_clock;
level2_clock:
process (mc_sleep_wpc, mc_wg_int, replace_2by0,

replace_2by1, wpc_level2)

variable m : integer;

begin
if (mc_sleep_wpc or (not mc_wg_int) or replace_2by0 or

replace_2by1) = ‘1’ then

clksel2 <= (others => ‘0’);

else

m := CONV_INTEGER ( wpc_level2 );
for i in clksel3‘range loop
if i = m then

clksel2(i) <= ‘1’;

else

clksel2(i) <= ‘0’;

end if;

end loop;

end if;

end process level2_clock;
level3_clock:
process (mc_sleep_wpc, mc_wg_int, replace_3by0,

replace_3by1, replace_3by2, wpc_level3)

variable m : integer;

begin
if (mc_sleep_wpc or (not mc_wg_int) or replace_3by0

or replace_3by1 or replace_3by2) = ‘1’ then

clksel3 <= (others => ‘0’);

else

m := CONV_INTEGER ( wpc_level3 );
for i in clksel3‘range loop
if i = m then

clksel3(i) <= ‘1’;

else

clksel3(i) <= ‘0’;

end if;

end loop;

end if;

end process level3_clock;
sel3 <= mc_sleep_wpc & mc_wg_int & replace_3by2 &

replace_3by1 & replace_3by0;

sel2 <= mc_sleep_wpc & mc_wg_int & replace_2by1

& replace_2by0;

sel1 <= mc_sleep_wpc & mc_wg_int & replace_1by0;
process (sel1, sel2, sel3)

begin

case sel3 is

when “01001” =>

lv13_mux_ctrl <= “00”; -- level 0

when “01010” =>

lv13_mux_ctrl <= “01”; -- level 1

when “01100” =>

lv13_mux_ctrl <= “10”; -- level 2

when “01000” =>

lv13_mux_ctrl <= “11”; -- level 3

when others =>

lv13_mux_ctrl <= “00”; -- defaults to normal clock

end case;
case sel2 is

when “0101” =>

lv12_mux_ctrl <= “00”; -- level 0

when “0110” =>

lv12_mux_ctrl <= “01”; -- level 1

when “0100” =>

lv12_mux_ctrl <= “10”; -- level 2

when others =>

lv12_mux_ctrl <= “00”; -- defaults to normal clock

end case;
case sel1 is

when “011” =>

lv11_mux_ctrl <= “00”; -- level 0

when “010” =>

lv11_mux_ctrl <= “01”; -- level 1

when others =>

lv11_mux_ctrl <= “00”; -- defaults to normal clock

end case;

end process;

end ;

1. An integrated delay locked loop circuit for write precompensation and clock recovery connected to receive source of multiple clock signals, each of different relative phase, comprising:
a plurality of clock selection multiplexers each connected to receive said multiple clock signals; and
a control circuit connected to control each of said plurality of clock selection multiplexers to pass a respective selected one of said multiple clock signals to a clock selection output, wherein if one clock selection multiplexer is selected to pass a particular one of said clock signals to its clock selection output, the other clock selection multiplexers are prevented from passing said particular one of said clock signals to their respective clock selection outputs.

2. The circuit of claim 1 further comprising a plurality of output multiplexers, each connected to receive outputs from said clock selection multiplexers, each having an output, and each being controlled by said control circuit to select which of said clock selection multiplexer outputs is passed to said output multiplexer output.

3. The circuit of claim 2 wherein said clock selection multiplexers are pass gate multiplexers.

4. The circuit of claim 2 further comprising a read multiplexer connected to receive said multiple clock signals and a read selection signal connected to control said read multiplexer to select at least one of said multiple clock signals for delivery to a read clock output.

5. The circuit of claim 2 wherein multiple clock signals include 64 signals, spaced 1/32π radians apart, and said plurality of clock selection multiplexers include four multiplexers.

6. The circuit of claim 2 wherein said output multiplexers are 4-to-1 multiplexers.

7. The circuit of claim 6 wherein said plurality of output multiplexers include four 4-to-1 multiplexers.

8. A delay locked loop circuit comprising:
a source of multiple clock signals, each of different relative phase;
a plurality of clock selection multiplexers each connected to receive said multiple clock signals;
a control circuit connected to control each of said plurality of clock selection multiplexers to pass a respective selected one of said multiple clock signals to a clock selection output, wherein if one clock selection multiplexer is selected to pass a particular one of said clock signals to its clock selection output, the other clock selection multiplexers are prevented from passing said particular one of said clock signals to their respective clock selection outputs; and
a plurality of output multiplexers, each connected to receive outputs from said clock selection multiplexers, each having an output, and each being controlled by said control circuit to select which of said clock selection multiplexer outputs is passed to said output multiplexer output.

9. The circuit of claim 8 wherein said clock selection multiplexers are pass gate multiplexers.

10. The circuit of claim 8 further comprising a read multiplexer connected to receive said multiple clock signals and a read selection signal connected to control said read multiplexer to select at least one of said multiple clock signals for delivery to a read clock output.

11. The circuit of claim 8 wherein multiple clock signals include 64 signals, spaced 1/32π radians apart, and said plurality of clock selection multiplexers include four multiplexers.

12. The circuit of claim 8 wherein said output multiplexers are 4-to-1 multiplexers.

13. The circuit of claim 8 wherein said plurality of output multiplexers include four 4-to-1 multiplexers.

14. A method for selecting write precompensating clock signals in a mass data storage device, comprising:
providing a plurality of clock selection multiplexers to each receive multiple phase separated clock signals;
providing selection signals to said clock selection multiplexers to pass a respective selected one of said multiple clock signals to a clock selection output, wherein if one clock selection multiplexer is selected to pass a particular one of said clock signals to its clock selection output, the other clock selection multiplexers are prevented from passing said particular one of said clock signals to their respective clock selection outputs.

15. The method of claim 14 further comprising providing a plurality of output multiplexers connected to receive outputs from said clock selection multiplexers, and controlling each of said output multiplexers to select which of said clock selection multiplexer outputs is passed as a circuit output.

16. The method of claim 15 wherein said providing clock selection multiplexers comprises providing pass gate multiplexers.

17. The method of claim 15 further comprising providing a read multiplexer connected to receive said multiple clock signals and a read selection signal connected to control said read multiplexer to select at least one of said multiple clock signals for delivery to a read clock output.

18. A method for selecting write precompensating clock signals in a mass data storage device, comprising:
providing a plurality of clock selection multiplexers to each receive multiple phase separated clock signals;
providing selection signals to said clock selection multiplexers to pass a respective selected one of said multiple clock signals to a clock selection output, wherein if one clock selection multiplexer is selected to pass a particular one of said clock signals to its clock selection output, the other clock selection multiplexers are prevented from passing said particular one of said clock signals to their respective clock selection outputs;
and providing a plurality of output multiplexers connected to receive outputs from said clock selection multiplexers, and controlling each of said output multiplexers to select which of said clock selection multiplexer outputs is passed as a circuit output.

19. The method of claim 18 wherein said providing clock selection multiplexers comprises providing pass gate multiplexers.

20. The method of claim 18 further comprising providing a read multiplexer connected to receive said multiple clock signals and a read selection signal connected to control said read multiplexer to select at least one of said multiple clock signals for delivery to a read clock output.
